(19) United States
(12) Patent Application Publication
(10) Pub. No.: US 2016/0190085 A1
(43) Pub. Date: Jun. 30, 2016

(54) MANUFACTURING METHOD OF SEMICONDUCTOR MODULE

(71) Applicant: TOYOTA JIDOSHA KABUSHIKI KAISHA, Toyota-shi (JP)

(72) Inventor: Akira KATO, Toyota-shi (JP)

(73) Assignee: TOYOTA JIDOSHA KABUSHIKI KAISHA, Toyota-shi (JP)

(21) Appl. No.: 14/959,468

(22) Filed: Dec. 4, 2015

(30) Foreign Application Priority Data
Dec. 25, 2014 (JP) 2014-261498

(51) Int. Cl. H01L 23/00; H01L 21/56; H01L 21/48

(52) U.S. Cl. CPC H01L 24/27; H01L 21/4825; H01L 21/565; H01L 2224/2746; H01L 2224/27848

(57) ABSTRACT

A manufacturing method of a semiconductor module, includes: forming a Ni plating layer on a surface of a first lead frame; forming a Au plating layer on a surface of the Ni plating layer; manufacturing an intermediate body that a semiconductor element is soldered to the first lead frame; forming a primer layer by applying a primer to a surface of the intermediate body and then drying the primer; molding a sealing resin body on a surface of the primer layer; and performing heat treatment so that Ni included in the Ni plating layer is dispersed in the Au plating layer.

### INCORPORATION BY REFERENCE

The disclosure of Japanese Patent Application No. 2014-261498 filed on Dec. 25, 2014 including the specification, drawings and abstract is incorporated herein by reference in its entirety.

### BACKGROUND OF THE INVENTION

1. Field of the Invention

The present invention relates to a manufacturing method of a semiconductor module in which a lead frame is connected to a semiconductor element via a solder layer and a sealing resin body is formed around the lead frame and the semiconductor element.

2. Description of Related Art

As a semiconductor module (a power module or a power card) provided with a semiconductor element such as an IGBT (Insulated Gate Bipolar Transistor), there are various configurations such as: a configuration in which a semiconductor body configured such that a lead frame is connected to a semiconductor element via a solder layer is accommodated in a case and a sealing resin body is formed in the case; and a configuration that is a caseless structure and in which the laminated body is sealed with a relatively hard sealing resin body. Note that, in either case of the caseless structure or a structure equipped with a case, a structure in which a heat sink, a cooler for circulating refrigerant, and the like are further disposed so that heat from a semiconductor element is dissipated by them is generally applied. Further, there is such a semiconductor module with a double-sided cooling structure in which lead frames are provided on an upper side and a lower side, a semiconductor element is disposed therebetween, and cooling structures are formed in the lead frames on the upper side and the lower side.

In the semiconductor module, in order to increase an adhesion property between the lead frame and the sealing resin body, a method in which a primer layer is provided therebetween is applied.

More specifically, a primer solution is applied to a surface of a metal face material by spin coat or the like, and after the primer solution is dried, sealing resin is potted thereto, thereby forming a sealing resin body around the lead frame.

In the meantime, a good wetting property between a lead frame and a solder is demanded for the lead frame, but particularly in the semiconductor module with the double-sided cooling structure, in a case where a wetting property of the upper lead frame with respect to a solder is insufficient, the solder may flow into a semiconductor-element side below the upper lead frame at the time of soldering, so a particularly high wetting property is demanded.

In view of this, like a semiconductor device described in Japanese Patent Application Publication No. 2007-103909 (JP 2007-103909 A), a technique in which Au plating having a better wetting property with respect to a solder than Ni plating is performed on a Ni plating layer can be applied.

However, as compared with the Ni plating, the Au plating has a low adhesion property with respect to a primer provided in order to raise an adhesion property with respect to a sealing resin body.

In view of this, as described in Japanese Patent Application Publication No. 2013-182978 (JP 2013-182978 A), in order to increase an adhesion property between the lead frame and the sealing resin body, the following method is used instead of using the primer: a surface treatment is performed on a lead frame to increase surface roughness so that an uneven surface is impregnated with a sealing resin body, and thus, an adhesion property therebetween is raised by an anchor effect.

However, since the surface roughness of the lead frame increases, a wetting property with respect to the solder turns worse this time. Moreover, at the time when a semiconductor element is provided on a surface of a lead frame via a solder layer, a surface treatment agent used for surface treatment on the lead frame may make contact with the semiconductor element.

### SUMMARY OF THE INVENTION

The present invention provides a manufacturing method of a semiconductor module that satisfies both a good wetting property between a lead frame and a solder and a high adhesion property between a lead frame or the like and a sealing resin body.

A manufacturing method of a semiconductor module, according to an aspect of the present invention includes: forming a Ni plating layer on a surface of a first lead frame; forming a Au plating layer on a surface of the Ni plating layer; manufacturing an intermediate body that a semiconductor element is soldered to the first lead frame;

forming a primer layer by applying a primer to a surface of the intermediate body and then drying the primer; molding a sealing resin body on a surface of the primer layer; and

performing heat treatment so that Ni included in the Ni plating layer is dispersed in the Au plating layer.

In the above aspect, after the Ni plating layer is formed on a surface of the lead frame made of Cu, for example, and the Au plating layer is formed on a surface of the Ni plating layer, heat treatment is performed before or after soldering the semiconductor element to the lead frame, so that Ni plating from the Ni plating layer below the Au plating layer is dispersed in the Au plating layer. Hereby, it is possible to manufacture a semiconductor module guaranteeing a good wetting property of the Au plating layer with respect to a solder and guaranteeing a high adhesion property with respect to the primer by the Ni plating dispersed in the Au plating layer.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a schematic view illustrating a first step of a manufacturing method of a semiconductor module, according to an embodiment of the present invention;

FIG. 2 is a schematic view illustrating the first step of the manufacturing method of the semiconductor module, according to the embodiment of the present invention, subsequently to FIG. 1;

FIG. 3 is a schematic view illustrating a second step and a third step of the manufacturing method of the semiconductor module, according to the embodiment of the present invention, and is a view illustrating Embodiment 1 of the semiconductor module manufactured herein;

FIG. 4 is a view illustrating Embodiment 2 of the semiconductor module manufactured by the manufacturing method of the present invention;

FIG. 5 is a view illustrating experimental results related to a heat treatment time and a diffusing amount of Ni; and

FIG. 6 is a view showing experimental results related to a relationship between a diffusing amount of Ni in an Au plating layer and a shear strength between the Au plating layer and a primer.

### DETAILED DESCRIPTION OF EMBODIMENTS

With reference to the drawings, the following describes embodiments of a manufacturing method of a semiconductor module of the present invention and a semiconductor module manufactured by this method. Note that the semiconductor module to be manufactured is not limited to examples illustrated herein at all, and the semiconductor module may have a configuration in which a semiconductor element is provided on a base material constituted by an insulated substrate, a stress relaxation plate, or the like, or a configuration in which a semiconductor element is provided on a surface of a laminated body of two or more types of base materials, other than a lead frame having a configuration illustrated herein. Further, in the examples illustrated herein, a cooler or the like is not illustrated.

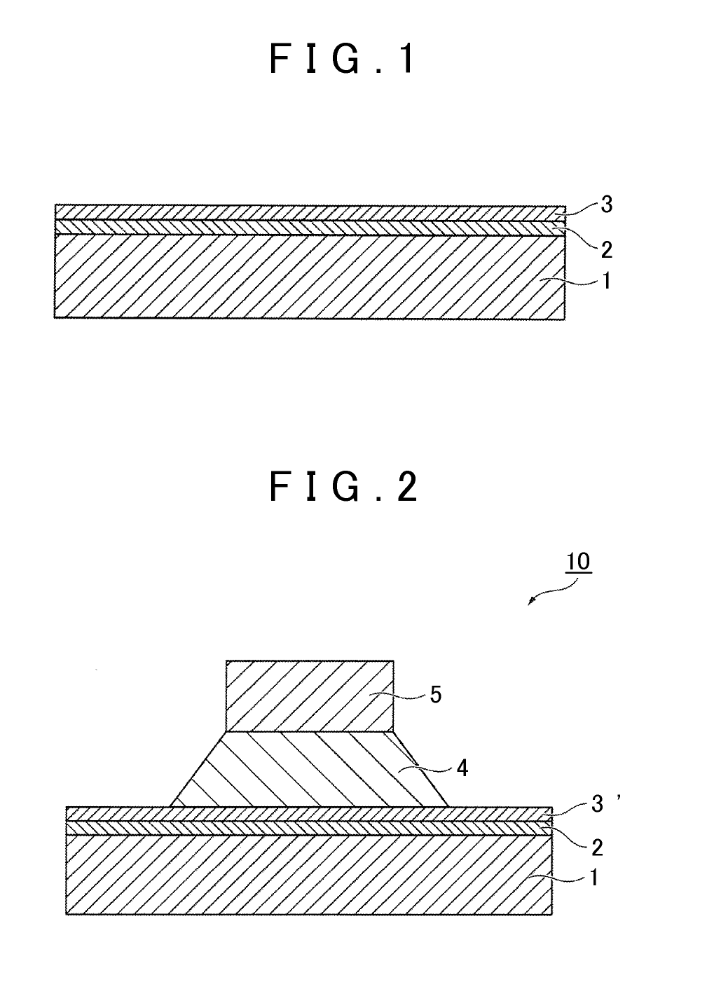

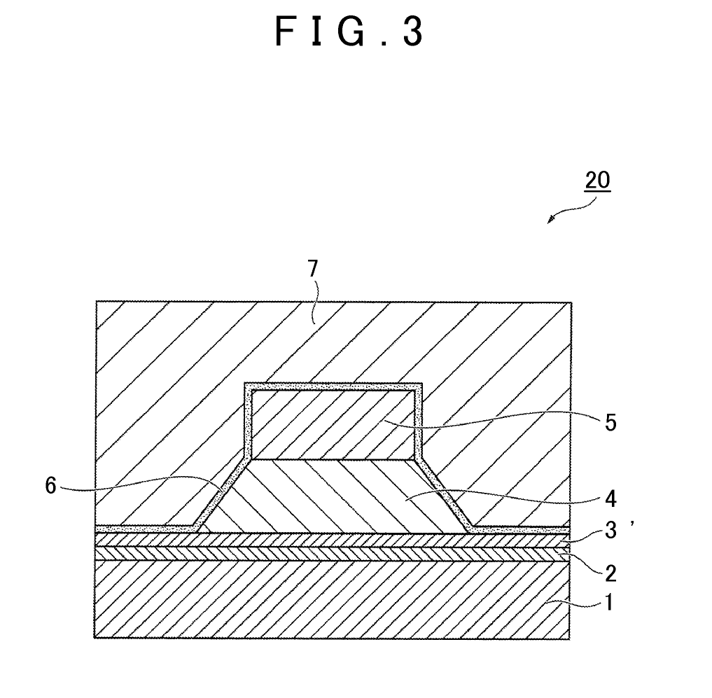

FIGS. 1, 2 are schematic views sequentially illustrating a first step of a manufacturing method of a semiconductor module, according to an embodiment of the present invention. FIG. 3 is a schematic view illustrating a second step and a third step of the manufacturing method of the semiconductor module, according to the embodiment of the present invention, and is a view of Embodiment 1 of the semiconductor module manufactured herein.

Initially, as illustrated in FIG. 1, a Ni plating layer 2 is formed on a surface of a lead frame 1, and further an Au plating layer 3 is formed on a surface of the Ni plating layer 2. Here, the lead frame 1 is made of aluminum, its alloy, a copper, its alloy, or the like.

Subsequently, as illustrated in FIG. 2, heat treatment is performed on the lead frame 1, the Ni plating layer 2, and the Au plating layer 3, so as to form an Au plating layer 3′ configured such that Ni is dispersed in a surface thereof on a solder-layer-4 side.

Here, it is preferable to perform the heat treatment at 215° C. or more for one hour or more. As will be described in the after-mentioned experimental results, by performing the heat treatment under the heat treatment condition, a Ni concentration in a surface of the Au plating layer 3′ on a solder-layer-4 or primer-layer-6 side can be set to 9 at % or more. Further, by setting the Ni concentration in the surface of the Au plating layer 3′ to 9 at % or more, it is possible to realize a high shear strength between the Au plating layer 3′ and the primer layer 6.

In FIG. 2, when the Au plating layer 3′ configured such that Ni is dispersed in the surface thereof on the solder-layer-4 side is formed, a semiconductor element 5 is provided on the lead frame 1 via the solder layer 4, so that an intermediate body 10 constituted by the lead frame 1 and the semiconductor element 5 is manufactured (a first step).

Here, the solder layer 4 may be made of a Pb solder or a Pb-free solder, but in order to reduce an environmental impact load, it is preferable that the solder layer 4 be made of a Pb-free solder such as a Sn—Ag solder, a Sn—Cu solder, a Sn—Ag—Cu solder, a Sn—Zn solder, and a Sn—Sb solder.

Note that a timing for forming the Au plating layer 3′ configured such that Ni is dispersed in the surface thereof on the solder-layer-4 side, by performing the heat treatment, is not limited to the example illustrated herein, and the formation of the Au plating layer 3′ may be performed after the semiconductor element 5 is provided on the lead frame 1 via the solder layer 4.

Since the solder layer 4 is formed via the Au plating layer 3′, a good wetting property between the Au plating layer 3′ and the solder layer 4 is guaranteed.

Subsequently, as illustrated in FIG. 3, a solution primer is applied, by spin coat or the like, over an area from the surface of the Au plating layer 3′ on a surface of the lead frame 1 constituting the intermediate body 10 to the surface of the solder layer 4 and the surface of the semiconductor element 5, and then, the solution primer is dried to form a primer layer 6.

Since the primer layer 6 is formed on the Au plating layer 3′ in the surface of which Ni is dispersed, on the surface of the lead frame 1, a high adhesion property with respect to the primer layer 6 is guaranteed by Ni dispersed in the Au plating layer 3′.

Then, as illustrated in FIG. 3, sealing resin is potted on an upper part of the primer layer 6. After the sealing resin is hardened so that a sealing resin body 7 is formed, a semiconductor module 20 is manufactured.

Here, a sealing resin material to be used includes epoxy thermo setting resin. The epoxy thermo setting resin is heat-curing synthetic resin having a reactive epoxy function in a terminal, and includes bisphenol-A epoxy resin manufactured by condensation reaction between bisphenol A and epichlorohydrin, novolak epoxy resin, trisphenolmethane epoxy resin, bisphenol-F epoxy resin, polyfunctional epoxy resin, flexible epoxy resin, biphenyl epoxy resin, high-molecular epoxy resin, glycidyl ester epoxy resin, and the like. These can be used solely or bisphenol-A epoxy resin and one or more of the other types can be used by mixing.

Further, for the purpose of improvement of the thermal conductivity and the thermal expansion, the epoxy thermo setting resin may contain inorganic fillers such as silica, alumina, boron nitride, silicon nitride, silicon carbide, and magnesium oxide.

According to the manufacturing method of the semiconductor module as illustrated herein, the Au plating layer 3′ in the surface of which Ni is dispersed is formed by dispersing Ni plating into the Au plating layer 3 from the Ni plating layer 2 placed below the Au plating layer 3. Hereby, while a good wetting property between the Au plating layer 3′ and the solder layer 4 is guaranteed, it is possible to guarantee a high adhesion property with respect to the primer layer 6 by Ni dispersed particularly in the surface of the Au plating layer 3′. Accordingly, it is possible to manufacture the semiconductor module 20 in which detachment of the sealing resin body 7 from the lead frame 1 is restrained.

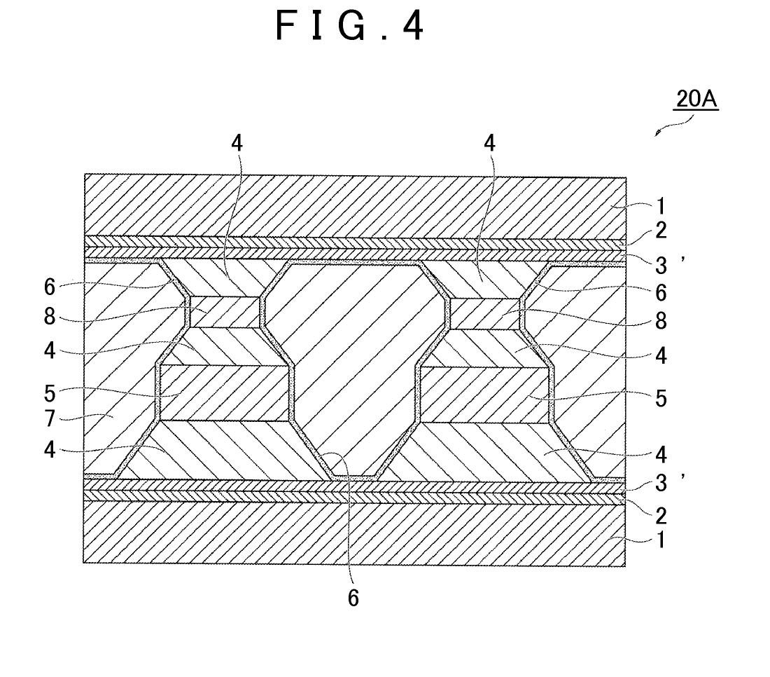

Further, FIG. 4 is a schematic view to describe a semiconductor module, according to Embodiment 2, which is manufactured by the manufacturing method of the semiconductor module of the present invention.

A semiconductor module 20A described herein is a semiconductor module of a so-called double-sided cooling structure. The semiconductor module 20A includes two lead frames 1, 1 on upper and lower sides, and is configured such that a semiconductor element 5 is soldered to the lower lead frame 1 and a copper block body 8 is soldered between the semiconductor element 5 and the upper lead frame 1. Thus, the semiconductor module 20A is constituted by the upper and lower lead frames 1, 1, the semiconductor element 5, the block body 8, and a sealing resin body 7. Note that, in the configuration illustrated herein, two semiconductor elements 5 are provided in parallel between the upper and lower lead frames 1, 1.

In a semiconductor module with a double-sided cooling structure, in a case where a wetting property of an upper lead frame with respect to a solder layer is insufficient, a solder may flow into a semiconductor-element side below the upper lead frame at the time of soldering, which may cause short circuit with other signal lines. However, in the semiconductor module 20A with the double-sided cooling structure as illustrated herein, since an Au plating layer 3′ in a surface of which Ni is dispersed is formed between the upper lead frame 1 and a solder layer 4, such a problem that a solder flows into a semiconductor-element side below the upper lead frame 1 at the time of soldering does not occur, and thus, there is no concern that short circuit with other signal lines is caused due to flowing of the solder occurs.

The inventors of the present invention performed experiments on a heat treatment time and a diffusing amount of Ni. More specifically, three temperatures, 210° C., 300° C., and 350° C. were selected, and Ni diffusing amounts at the time when heat treatment was performed for respective heat treatment times of 10, 40, 60 minutes under each of the temperature conditions were measured. Experimental results are shown in

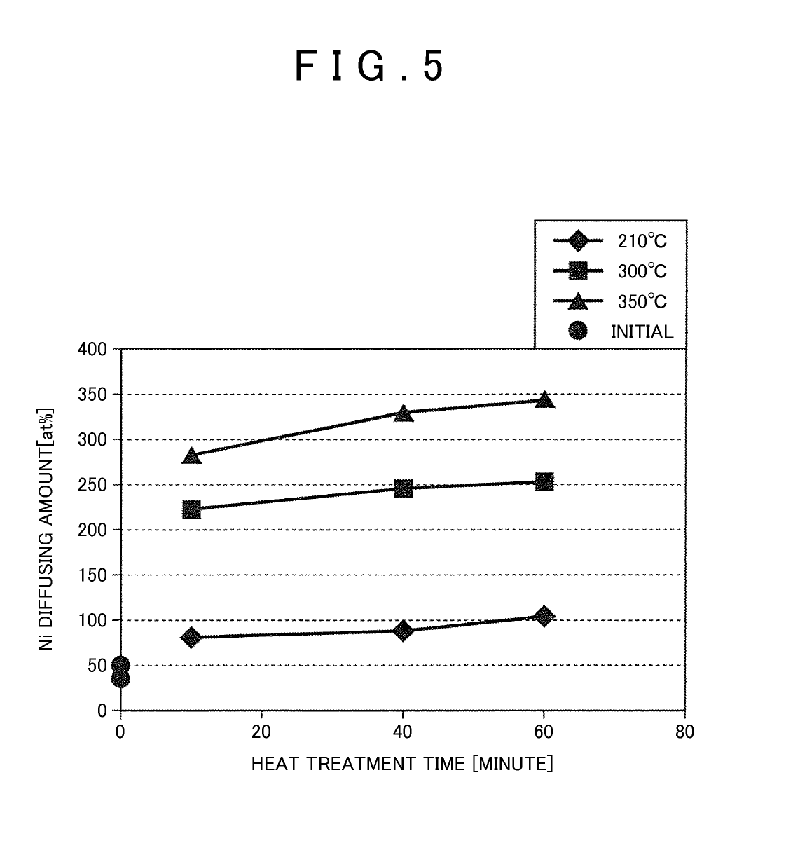

FIG. 5.

From FIG. 5, it is found that, in a case of a temperature of 210° C., a treatment time during which the Ni diffusing amount reaches 9 at % is 60 minutes, and in a temperature condition higher than 210° C., the Ni diffusing amount reaches 20 at % or more in ten minutes.

Then, from the Ni diffusing amounts under three temperature conditions and three treatment time conditions in the experiments, a Ni diffusion speed expressed by Mathematical Expression 1 as follows can be calculated by uses of the Arrhenius plot.

$$Nickel diffusing amount ( at \% ) = {t}^{\frac{1}{9}} * \sqrt{17624491} * exp ( - \frac{61227.622}{2 * 8.314 T} ) + 3.82 \qquad ( Math 1 )$$

Here, t indicates a treatment time (sec) and T indicates a temperature (K).

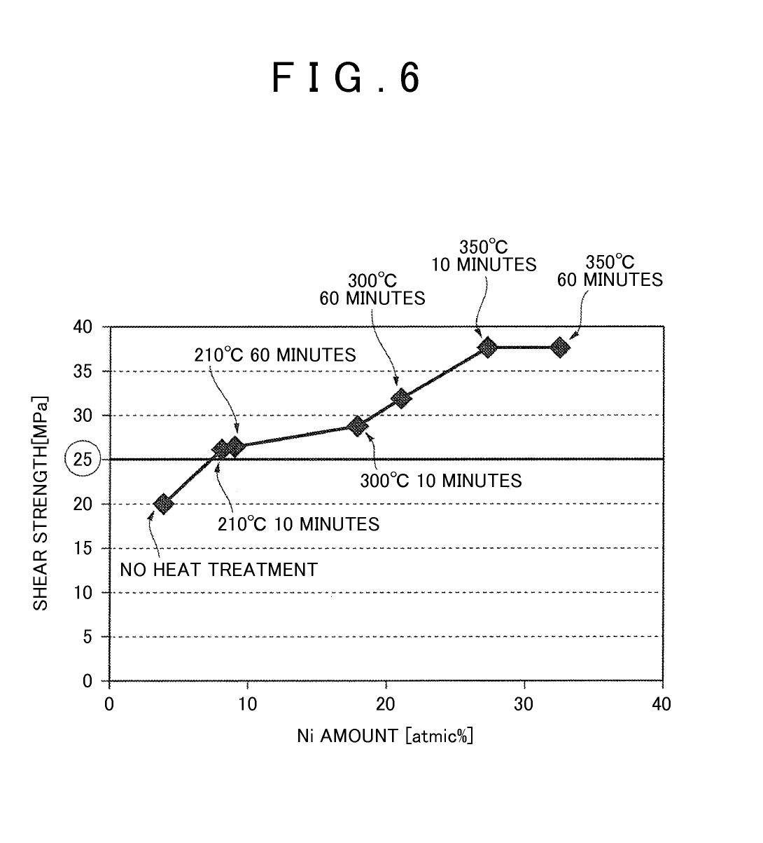

The inventors selected test specimens treated for a heat treatment time of 10 minutes and test specimens treated for a heat treatment time of 60 minutes from among test specimens manufactured under the three temperature conditions and the three treatment time conditions, so as to further perform experiments to measure a shear strength between an Au plating layer and a primer. Experimental results are shown in FIG. 6.

From FIG. 6, it is demonstrated that the test specimen heat-treated at 210° C. for ten minutes has a shear strength of 25 MPa, which is an extremely high shear strength, and thus, it is found that the other test specimens can have a further higher shear strength.

Here, in the present embodiment, the “lead frame” not only indicates a lead frame literally, but also includes a die pad, substrates such as a circuit board and a stress relaxation substrate, a DBA (insulated substrate) configured such that a substrate made of pure Al and a substrate made of AlN (aluminum nitride) are laminated, a heat sink, and the like.

In the diffusion of the Ni plating into the Au plating layer in the first step, it is necessary for the Ni plating to make contact with the primer layer. Accordingly, it is desirable for the Ni plating to be dispersed particularly in a surface of the Au plating layer.

Further, the sealing resin body in the third step can be formed by a suitable molding method selected from general molding methods such as compression molding, transfer molding, and injection molding of a resin material such as epoxy thermo setting resin.

Here, it is preferable to perform the heat treatment in the first step at 215° C. or more for one hour or more.

The inventors have specified that, by performing the heat treatment under the heat treatment condition of 215° C. or more for one hour or more, a Ni concentration in the surface of the Au plating layer on the solder-layer or primer-layer side can be adjusted to 9 at % (atmic %) or more in terms of an Au-concentration ratio.

Further, it is demonstrated that, in a case where the Ni concentration in the surface of the Au plating layer on the solder-layer side is 9 at % or more, a shear strength between the Au plating layer in which the Ni plating is dispersed and the primer layer exhibits an extremely high strength of 25 Mpa or more, which exceeds the strength of the Ni plating itself.

Further, another embodiment of the manufacturing method of the semiconductor module, according to the present invention, is as follows: in the first step, two lead frames on upper and lower sides are prepared, a semiconductor element is soldered to the lower lead frame, and a copper block body is soldered between the semiconductor element and the upper lead frame, so as to manufacture an intermediate body constituted by the upper and lower lead frames and the semiconductor element.

The manufacturing method of the present embodiment is targeted for the aforementioned semiconductor module with the double-sided cooling structure.

In the manufacturing method of the present invention, the Au plating layer having a good wetting property with respect to the solder is provided on the surface of the lead frame. Accordingly, when soldering is performed particularly on the upper lead frame constituting the semiconductor module with the double-sided cooling structure, such a problem that a solder flows into a semiconductor-element side below the upper lead frame does not occur.

As is understood from the above description, according to the manufacturing method of the semiconductor module of the present invention, after a Ni plating layer is formed on a surface of a lead frame and an Au plating layer is formed on a surface of the Ni plating layer, heat treatment is performed before or after a semiconductor element is soldered to the lead frame, so that Ni plating from the Ni plating layer below the Au plating layer is dispersed in the Au plating layer. Hereby, it is possible to manufacture the semiconductor module in which detachment of a sealing resin body from the lead frame or the like is restrained, while guaranteeing a good wetting property of the Au plating layer with respect to the solder and guaranteeing a high adhesion property with respect to the primer by the Ni plating dispersed in the Au plating layer.

Thus, the embodiments of the present invention have been described with reference to the drawings, but concrete configurations of the present invention are not limited to the above embodiments. Even if there are changes of design or the like within a range that does not deviate from a gist of the present invention, they are included in the present invention.

What is claimed is:

1. A manufacturing method of a semiconductor module, comprising:
forming a Ni plating layer on a surface of a first lead frame;
forming a Au plating layer on a surface of the Ni plating layer;
manufacturing an intermediate body that a semiconductor element is soldered to the first lead frame;
forming a primer layer by applying a primer to a surface of the intermediate body and then drying the primer;
molding a sealing resin body on a surface of the primer layer; and
performing heat treatment so that Ni included in the Ni plating layer is dispersed in the Au plating layer.

2. The manufacturing method of the semiconductor module, according to claim 1, wherein
the heat treatment is performed at 215° C. or more for one hour or more.

3. The manufacturing method of the semiconductor module, according to claim 2, wherein
an Ni concentration in a surface of the Au plating layer on a solder-layer or primer-layer side is set to 9 at % or more.

4. The manufacturing method of the semiconductor module, according to claim 1, wherein
a second lead frame is placed above the semiconductor element constituting the intermediate body, and a copper block body is soldered between the semiconductor element and the second lead frame.
